(19) United States
(12) Patent Application Publication
(10) Pub. No.: US 2006/0012028 A1
(43) Pub. Date: Jan. 19, 2006

(54) Device mounting board

(76) Inventors: Ryosuke Usui, Ichinomiya-City (JP); Hideki Mizuhara, Ichinomiya-City (JP); Yasunori Inoue, Ogaki-City (JP); Yusuke Igarashi, Isesaki-City (JP); Takeshi Nakamura, Isesaki-City (JP)

Correspondence Address: FISH & RICHARDSON P.C., P.O. BOX 1022, MINNEAPOLIS, MN, 55440-1022, US

(21) Appl. No.: 11/147,777

(22) Filed: Jun. 7, 2005

(30) Foreign Application Priority Data
Jun. 14, 2004 (JP) 2004-175069

(51) Int. Cl. H05K 1/11; H05K 1/00; H05K 5/00; H01L 23/48; H01L 23/12

(52) U.S. Cl. 257/700; 174/52.1; 174/250; 174/261; 257/738

(57) ABSTRACT

A device mounting board on which a device is mounted is provided with a substrate and an insulating film provided on one surface of the substrate. The substrate and the insulating film include glass fiber impregnated with epoxy resin. The epoxy resin impregnation ratio of the glass fiber included in the insulating resin film is higher than that of the glass fiber included in the substrate.

### BACKGROUND OF THE INVENTION

1. Field of the Invention

The present invention relates to a device mounting board on which a device is mounted.

2. Description of the Related Art

With portable electronic appliances such as mobile phones, PDAs, DVCs and DSCs becoming more and more advanced in their capabilities, miniaturization and weight reduction of products have become essential for market acceptance. Accordingly, highly-integrated system LSIs for achieving these goals are demanded. Also, better ease and convenience of use are required of these electronic appliances. In this respect, high capabilities and high performance are required of LSIs used in these appliances. While the number of I/Os is increasing as a result of increasingly high integration of LSI chips, there is also a persistent requirement for miniaturization of packages themselves. In order to meet these incompatible demands, development of a semiconductor package adapted for high-density substrate mounting of semiconductor devices is in serious demand.

Ball grid array (BGA) is known as an example of package adapted for a demand for high density. A BGA is formed such that semiconductor chips are mounted on a package substrate and then molded by resin. Solder balls are formed as terminals in selected areas on the opposite side. In BGA, an uninterrupted mounting area is secured so that miniaturization of a package is achieved relatively easily. The circuit board need not be adapted for small pitch and a high-precision mounting technology is not necessary. Therefore, by using BGA, the total mounting cost may become reduced even if the package cost is relatively high.

FIG. 12 is a schematic illustration of the structure of a BGA generally used. The BGA 100 is constructed such that an LSI chip 102 is mounted on a glass epoxy substrate 106 via an adhesive layer 108. The LSI chip 102 is molded by sealing resin 110. The LSI chip 102 and the glass epoxy substrate 106 are electrically connected by a metal wire 104. On the back surface of the glass epoxy substrate 106 are arranged solder balls 112 in arrays. The BGA 100 is mounted on a printed circuit board via the solder balls 112.

Patent document No. 1 describes an alternative example of CSP. In document No. 1 a system in package in which high-frequency LSIs are mounted is disclosed. In this package, a multilayer wiring structure is formed on a base substrate. Semiconductor devices such as high-frequency LSIs are formed thereon. The multilayer wiring structure is formed by a stack including a core substrate, a copper foil provided with an insulating resin layer and the like.

However, it is difficult to achieve a low profile of a level desired in future portable electronics with the related-art CSP.

Related Art List

Patent document No. 1 JP2002-94247

### SUMMARY OF THE INVENTION

The present invention has been done in view of the aforementioned circumstances and its object is to provide a thin device mounting board.

The device mounting board on which a device is mounted, according to one aspect of the present invention, the device mounting board comprises: a substrate which includes a first insulating film; a second insulating film which is provided on one surface of the substrate, wherein the first insulating film and the second insulating film include glass fiber impregnated with epoxy resin, and the epoxy resin impregnation ratio of the second insulating film is higher than that of the first insulating film.

The film thickness of the second insulating film may be smaller than that of the first insulating film. Wiring may be provided between the substrate and the second insulating film. The epoxy resin impregnation ratio of the second insulating film may range from 71 Vol % to 75 Vol %. The glass-transition temperature of the second insulating film may range from 160° C. to 170° C., and the bending modulus of elasticity of the second insulating film may range from 27 GPa to 30 GPa.

The device mounting board may further comprise a third insulating film provided on the other surface of the substrate, wherein the third insulating film includes glass fiber impregnated with epoxy resin, and the epoxy resin impregnation ratio of the third insulating film is higher than that of the first insulating film. The epoxy resin impregnation ratio of the third insulating film may range from 71 Vol % to 75 Vol %.

Wiring for connecting the devices may be provided on the second insulating film, and a fourth insulating film may be provided on the wiring so that the devices and the wiring are covered by the fourth insulating film. The fourth insulating film may be a photo solder resist layer including cardo type polymer.

### BRIEF DESCRIPTION OF THE DRAWINGS

FIG. 1 illustrates the structure of an ISB (TM).

FIGS. 2A and 2B illustrate a process of fabricating a BGA and an ISB (TM).

FIGS. 3A through FIG. 10B are sections illustrating the steps of fabricating a device mounting board according to an embodiment of the present invention.

FIGS. 11A to 11D are sections illustrating the structure of a semiconductor apparatus according to the embodiment.

FIG. 12 is a schematic illustration of the structure of an ordinary BGA according to the related art.

### DETAILED DESCRIPTION OF THE INVENTION

Before describing an embodiment of the present invention, a description will be given of an ISB structure employed in the embodiment. Integrated system in board TM (ISB) is a package developed by the applicant of the instant application. An ISB package is a coreless system in package, a type of electronic circuit packaging mainly comprising bare semiconductor chips, that has a copper wiring pattern but does not use a core (substrate) for supporting circuit components.

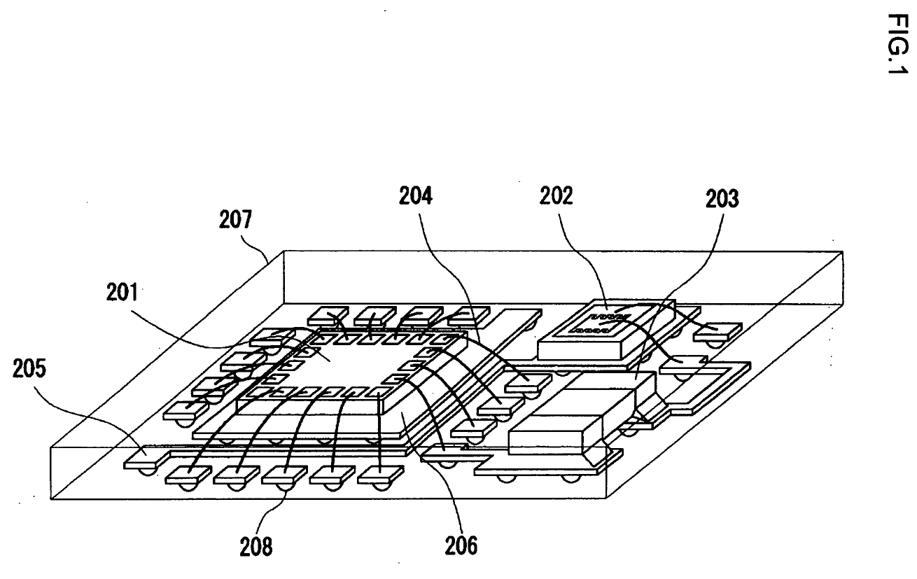

FIG. 1 is a schematic diagram illustrating the structure of an ISB. FIG. 1 only illustrates only a single wiring layer to help understand the overall structure of an ISB. Actually, a plurality of wiring layers are built upon one another. The ISB comprises an LSI bare chip 201, a Tr bare chip 202 and a chip CR 203 connected to each other by wiring comprising a copper pattern 205. The LSI bare chip 201 is electrically connected to an extraction electrode and wiring having a solder ball 208 on the bottom thereof, via a gold bonding wire 204. Immediately underneath the LSI bare chip 201 is provided conductive paste 206. The ISB is mounted on a printed circuit board via the conductive paste 206. The whole ISB is sealed by a resin package 207 formed of epoxy resin or the like.

According to this package, the following advantages are available.
(i) Since the package is coreless, small-sized and low-profile transistors, ICs and LSIs can be fabricated.
(ii) Since transistors, system LSIs, and capacitors and resistors of a chip type can be built into the circuit for packaging, a highly advanced system in package (SIP) is achieved.
(iii) By employing a combination of currently available semiconductor chips, a system LSI can be developed in a short period of time.
(iv) A semiconductor bare chip is directly mounted on a copper member directly underneath so that favorable heat dissipation is achieved.
(v) Since the circuit wiring is made of copper and not supported by any core material, a low-dielectric circuit wiring, exhibiting excellent characteristics in high-speed data transfer and high-frequency circuits, results.
(vi) Since electrodes are embedded inside the package, creation of particle contaminants derived from an electrode material is controlled.
(vii) The package size is free. Since the volume of discarded materials per one package is approximately 1/10 of a 64-pin SQFP package, the load placed on the environment is reduced.
(viii) A new system configuration, embodying a concept shift from a printed circuit board carrying components to a circuit board with built-in functions, is realized.
(ix) Designing an ISB pattern is as easy as pattern design of a printed circuit board so that engineers of a set manufacturer can design the pattern on their own.

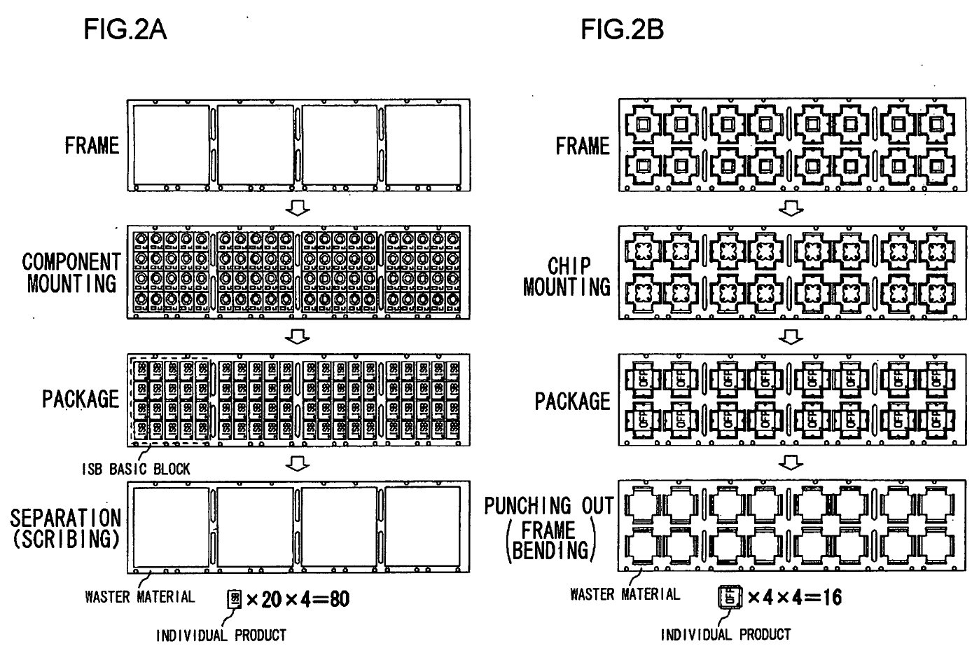

A description will now be given of merits in a process of fabricating an ISB. FIG. 2A illustrates a fabrication process for an ISB according to the present invention; and FIG. 2B illustrates a fabrication process for a related-art chip size package (CSP) by way of comparison. FIG. 2B illustrates a process of fabricating a CSP of the related art. Initially, a frame is formed on a base substrate. Chips are mounted in areas for devices given as partitions in the frame. Subsequently, a package is provided for each device using a thermosetting resin. Each of the devices is then punched out using a die. In the final punching-out step, a mold resin and a base substrate are simultaneously cut off, causing a problem such as that of roughened cut surface. Further, large amounts of waster materials that remain after the punching-out step present a problem due to their load on the environment.

FIG. 2A illustrates a process of fabricating an ISB. Initially, a frame is provided on a metal foil. Wiring patterns are formed in areas for module formation. Circuit devices such as LSIs are mounted on the pattern. Subsequently, packaging is applied to each of the modules. Dicing is performed along the scribed areas so as to deliver products. The underlying metal foil is removed after the packaging is completed and before the scribing step. Therefore, only the resin layer is diced in the scribe step. With this, roughening of the cut surface is suppressed and accuracy of dicing is improved.

### FIRST EMBODIMENT

FIG. 10B is a section illustrating a device mounting board 400 provided with a four-layer ISB structure according to the first embodiment.

The device mounting board 400 comprises a stack of an insulating resin layer 312 and a photo solder resist layer 328 built on the top surface of a substrate 302 in the stated order. A stack of the insulating resin film 312 and the photo solder resist layer 328 is built on the bottom surface of the substrate 302 in the stated order. The substrate 302 is an example of a substrate that includes a first insulating film. The insulating resin film 312 on the top surface of the substrate 302 is an example of “a second insulating film” according to the invention. The insulating resin film 312 on the bottom surface of the substrate 302 is an example of “a third insulating film” according to the invention. The photo solder resist layer 328 is an example of “a fourth insulating film” according to the invention.

The term “four-layer ISB structure” refers to a structure of four layers containing a wiring layer inside. The wiring layer is embedded inside the insulating resin 312 and the photo solder resist layer 328. Photosensitivity is required of the photo solder resist layer 328 because of a process for forming a via hole in the layer.

In the four-layer ISB structure, the insulating resin film 312 on the top surface and the insulating resin film 312 on the bottom surface sandwiching the substrate 302 may be formed of the same material. Also, the photo solder resist layer 328 on the top surface and the photo solder resist layer 328 on the bottom surface may be formed of the same material. With this, the fabrication process is simplified.

A through hole 327 that runs through the substrate 302, the insulating resin film 312 and the photo solder resist layer 328 is provided. Portions of the wiring formed of a copper film 308, portions of the wiring formed of a copper film 320 and portions of a via 311 are embedded in the substrate 302. Portions of the wiring formed of the copper film 308, portions of the wiring formed of a copper film 320, wiring 309, portions of the via 311 and portions of a via 323 are embedded in the insulating resin film 312. Portions of the wiring formed of the copper film 320 and portions of the via 323 are embedded in the photo solder resist layer 328. An opening 326 is provided in the photo solder resist layer 328.

The substrate 302 may be a resin substrate such as a glass epoxy substrate. For example, the substrate 302 may be a substrate that includes an insulating film formed of glass fiber impregnated with epoxy resin. The thickness of the substrate 302 is about 60 μm, for example.

A resin material that is softened when heated is used to form the insulating resin film 312. A resin material that includes glass fiber impregnated with epoxy resin described later is used. The epoxy resin impregnation ratio of the insulating resin film 312 is higher than that of the substrate 302.

Glass fiber is included so as to improve laser workability. For example, granular or fibrous SiO₂ or SiN is used as glass fiber. For example, the thickness of the insulating resin film 312 is about 40 μm.

The photo solder resist layer 328 is formed of, for example, a resin film including cardo type polymer. The thickness of the photo solder resist layer 328 is about 25 μm, for example.

cardo type polymer exhibits an excellent mechanical strength and heat resistance, and a small coefficient of linear expansion, due to an action of the bulk of a substituent group preventing the motion of a backbone. This helps mitigate degradation in adhesion or interlayer peeling occurring between the resin insulating film 312 and the photo solder resist layer 328 in a heat cycle.

The multi-layer wiring structure comprising the wiring formed of the copper film 308, the wiring formed of the copper film 320, the wiring 309, the via 311, the via 323 and the like may not necessarily be formed of copper wires. Aluminum wiring, aluminum alloy wiring, copper alloy wiring, gold bonding wires, gold alloy wiring and a mixture of these may also be used.

On top of the four-layer ISB structure or in the interior thereof may be provided active devices such as transistors and diodes or passive devices such as capacitors and resistors. These active devices and passive devices may be connected to the multi-layer wiring structure inside the four-layer ISB and connectable to an external conductive member via, for example, the via 323.

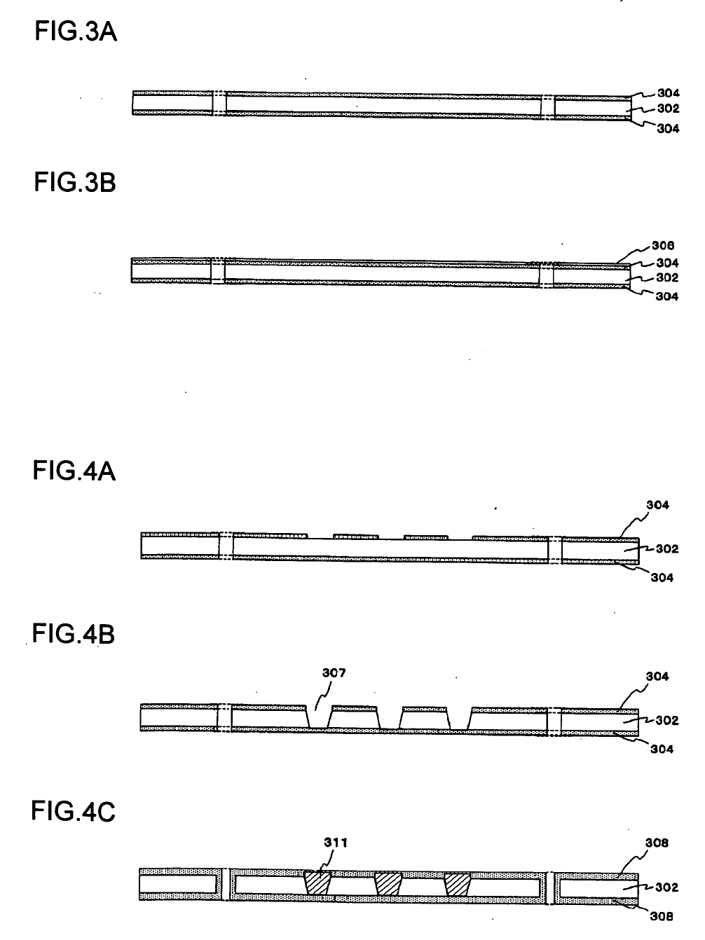

FIGS. 3A through 10B are sections illustrating the steps of fabricating the device mounting board 400 provided with the four-layer ISB structure according to the embodiment. First, as illustrated in FIG. 3A, the substrate 302, which is bonded with a copper foil 304 and provided with a drilled opening with a diameter of about 150 μm is prepared. The thickness of the substrate 302 is about 60 μm, for example, and the thickness of the copper foil 304 is in the range between 10 μm and 15 μm, for example. Subsequently, as illustrated in FIG. 3B, the top surface of the copper foil 304 is laminated with a photo etching resist layer 306.

The photo etching resist layer 306 is patterned by being exposed to light, using a glass as a mask. Subsequently, as illustrated in FIGS. 4A and 4B, a via hole 307 of a diameter of about 100 μm is formed by chemical etching by a chemical, using the photo etching resist layer 306 as a mask. Subsequently, the interior of the via hole 307 is roughened and cleaned by a wet process. As illustrated in FIG. 4C, electroless plating capable of high aspect ratio fill is conducted, followed by electroplating, which fills the interior of the via hole 307 by a conductive material. In this way, the via 311 is formed. After this, the copper film 308 is formed on the entirety of the composite.

For example, the via 311 may be formed as described below. A thin film of a thickness of about 0.5-1 μm is formed on the entirety of the via hole 307 using electroless copper plating, and then a film of about 20 μm is formed by electroplating. Normally, palladium is used as a catalyst for electroless plating. In order to attach a catalyst for electroless plating to a flexible insulating resin, palladium is contained in a water solution in the form of complex, the flexible insulating substrate is steeped in the solution so as to attach the palladium complex on the surface thereof, and the palladium complex is reduced to palladium as a metal, using a reducing agent. In this way, a core for plating is formed on the surface of the flexible insulating substrate.

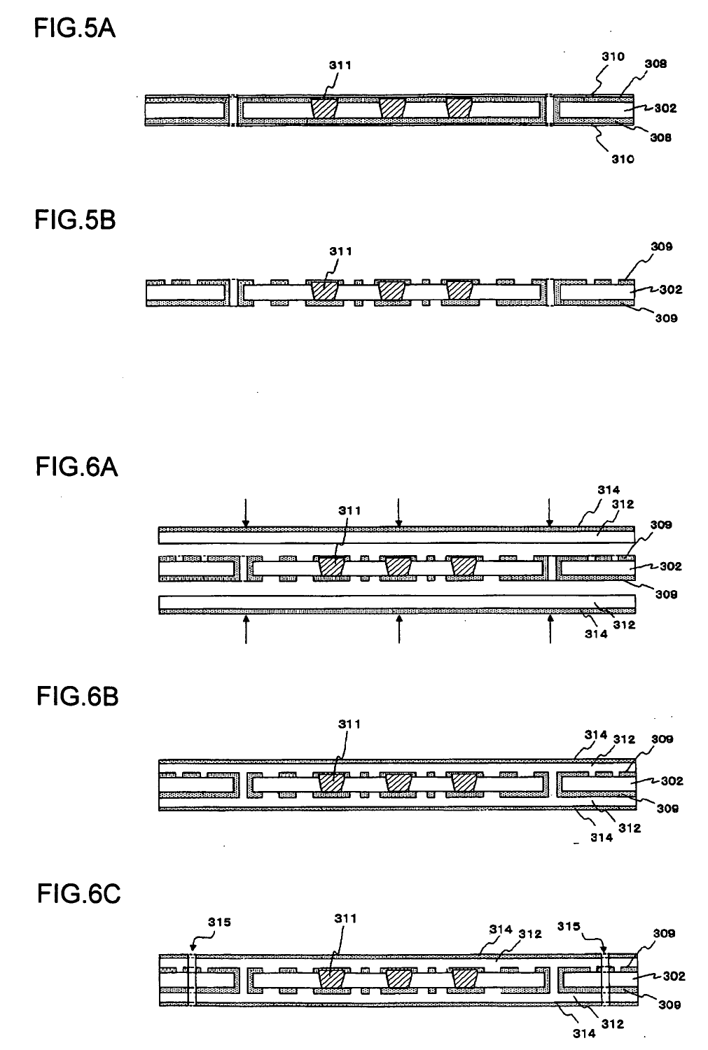

Subsequently, as illustrated in FIG. 5A, the top and bottom surfaces of the copper film 308 are laminated with a photo etching resist layer 310. Then, as illustrated in FIG. 5B, the photo etching resist layer 310 is patterned by being exposed to light, using a glass as a mask. The copper plating layer 308 is then etched using the photo etching resist layer 310 as a mask. In this way, the wiring 309 of copper is formed. For example, the wiring may be formed by spraying a chemical etchant on unnecessary portions of the copper plating where the plating is free of the resist and is exposed, and by removing the portions sprayed with the etchant by etching.

Subsequently, as illustrated in FIG. 6A, a composite of the insulating resin film 312 and the copper foil 314 is bonded to the wiring 309 from above and from below. The thickness of the insulating resin film 312 is about 40 μm, for example, and the thickness of the copper foil 314 is about 10 μm-15 μm. A resin material that is softened when heated is used to form the insulating resin film 312. For example, a resin material that includes glass fiber impregnated with epoxy resin described later is used. The epoxy resin impregnation ratio in the insulating resin film 312 is higher than that of the substrate 302.

For bonding, the composite of the insulating resin film 312 and the copper foil is brought into contact with the substrate 302 and the wiring 309. The substrate 302 and the wiring 309 are laid in the insulating resin film 312. Subsequently, as illustrated in FIG. 6B, the insulating resin film 312 is heated in a vacuum or under reduced pressure and is bonded to the substrate 302 and the wiring 309. Then, as illustrated in FIG. 6C, by irradiating the copper foil 314 with X ray, an opening 315 that runs through the copper foil 314, the insulating resin film 312, the wiring 309 and the substrate 302 is provided.

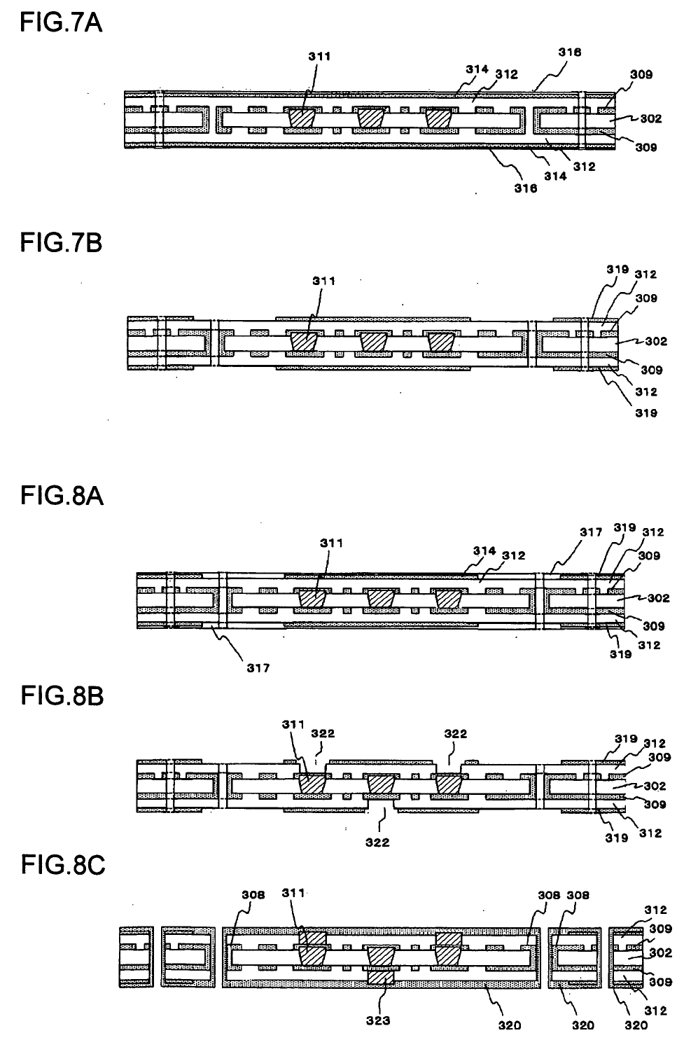

Subsequently, as illustrated in FIG. 7A, the top and bottom surfaces of the copper foil 314 are laminated with a photo etching resist layer 316. Then, as illustrated in FIG. 7B, the photo etching resist layer 316 is patterned by being exposed to light, using a glass as a mask. The copper foil 314 is then etched using the photo etching resist layer 316 as a mask. In this way, the wiring 319 of copper is formed. For example, the wiring may be formed by spraying a chemical etchant on unnecessary portions of the copper foil where the plating is free of the resist and is exposed, and by removing the portions sprayed with the etchant by etching.

Subsequently, as illustrated in FIG. 8A, the top and bottom surfaces of the wiring 319 are laminated with a photo etching resist layer 317. Then, as illustrated in FIG. 8B, the photo etching resist layer 317 is patterned by being exposed to light, using a glass as a mask. The wiring 319 is etched using the photo etching resist layer 317 as a mask. In this way, a via hole 322 of a diameter of about 100 nm is formed. Subsequently, the interior of the via hole 322 is roughened and cleaned by a wet process. As illustrated in FIG. 8C, electroless plating capable of high aspect ratio fill is conducted, followed by electroplating, which fills the interior of the via hole 322 by a conductive material. In this way, the via 323 is formed. After this, the copper film 320 is formed on the entirety of the composite.

For example, the via 323 may be formed as described below. A thin film of a thickness of about 0.5-1 μm is formed on the entirety of the via hole 322 using electroless copper plating, and then a film of about 20 μm is formed by electroplating. Normally, palladium is used as a catalyst for electroless plating. In order to attach a catalyst for electroless plating to a flexible insulating resin, palladium is contained in a water solution in the form of complex, the flexible insulating substrate is steeped in the solution so as to attach the palladium complex on the surface thereof, and the palladium complex is reduced to palladium as a metal, using a reducing agent. In this way, a core for plating is formed on the surface of the flexible insulating substrate.

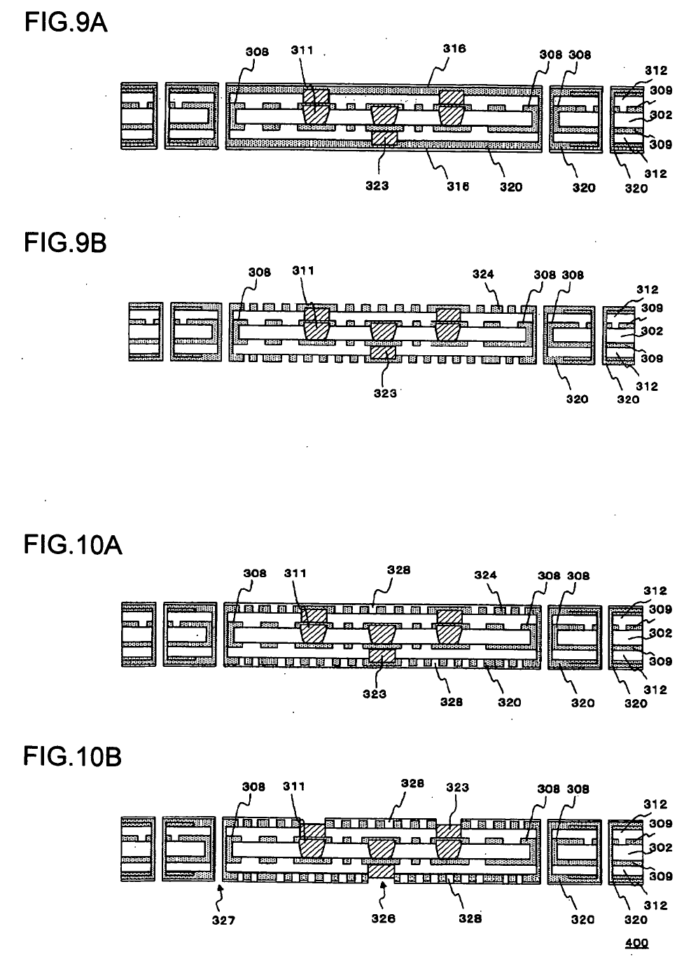

Subsequently, as illustrated in FIG. 9A, the top and bottom surfaces of the copper film 320 are laminated with a photo etching resist layer 316. Then, as illustrated in FIG. 9B, the copper film 320 is patterned by being exposed to light, using a glass as a mask. The copper film 320 is then etched using the photo etching resist layer 316 as a mask. In this way, wiring 324 of copper is formed. For example, the wiring may be formed by spraying a chemical etchant on unnecessary portions of the copper film where the film is free of the resist and is exposed, and by removing the portions sprayed with the etchant by etching.

Subsequently, as illustrated in FIG. 10A, the top and bottom surfaces of the wiring 324 are laminated with the photo solder resist layer 328. The thickness of the photo solder resist layer 328 is about 25 μm, for example. Lamination may be performed at a temperature of 110° C. and 1 atmospheric pressure. The duration of the process may be 1-2 minutes. This is followed by an after baking process which hardens portions of the photo solder resist layer 328. The photo solder resist layer 328 is formed of, for example, a resin film including cardo type polymer.

Then, as illustrated in FIG. 10B, the photo solder resist layer 328 is patterned by being exposed to light, using a glass as a mask. A via hole 326 of a diameter of about 100 μm is then formed by exposing the via 323 formed in the via hole 322, using the photo solder resist layer 328 as a mask. The via hole 326 according to this embodiment is formed by, for example, chemical etching using a chemical. Subsequently, the via 323 exposed is plated with gold (not shown).

A description will now be given of effects obtained by using the insulating resin film 312 characterized by a higher epoxy resin impregnation ratio than that of the substrate 302. The insulating film which is used as the insulating resin film 312 and which contains glass fiber impregnated with epoxy resin is of the epoxy resin impregnation ratio ranging from 71 Vol % to 75 Vol %. Therefore, it can be molded into a thin film using a predetermined additive, with the occurrence of voids or unevenness being suppressed. Thus, a film of a thickness of about 40 μm can be used for the insulating resin film 312. Compared with the thickness of 60 μm of a resin material ordinarily used for an insulating resin film, the thickness of the insulating resin film 312 is reduced to ⅔. By using an insulating film that contains glass fiber impregnated with epoxy resin as the insulating resin film 312, the thickness of the device mounting board 400 is reduced. Since the occurrence of voids or unevenness in bonding a film is suppressed, the composite of the insulating resin film 312 and a film bonded thereto, provided in the device mounting board 400, contains hardly any voids or unevenness. Accordingly, the stability in fabrication and reliability of the device mounting board 400 are improved.

The insulating resin film 312 that contains glass fiber impregnated with epoxy resin with a impregnation ratio higher than that of the substrate 302 may preferably have the following properties. The epoxy resin impregnation ratio may range from 71 Vol % to 75 Vol %. When the epoxy resin impregnation ratio is within this range, the film can be produced by molding with the occurrence of voids or unevenness being controlled.

The glass-transition temperature (Tg) of the insulating resin film that contains glass fiber impregnated with epoxy resin may range, for example, from 160° C. to 170° C. When the glass-transition temperature is within this range, the film can be fabricated in a stable manner using an ordinary method. The glass-transition temperature may be measured by a dynamic viscoelasticity measurement (DMA) using a bulk sample. The bending modulus of elasticity of the insulating resin film that includes glass fiber impregnated with epoxy resin may range, for example, from 27 GPa to 30 GPa. When the bending modulus of elasticity is within this range, the rigidity of the insulating resin film is improved so that fabrication of a thin film is possible correspondingly.

### SECOND EMBODIMENT

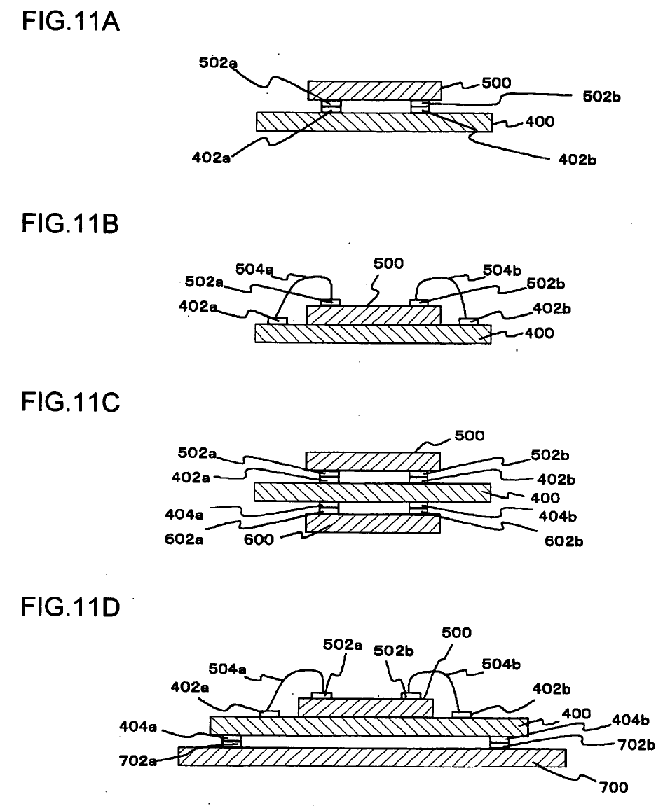

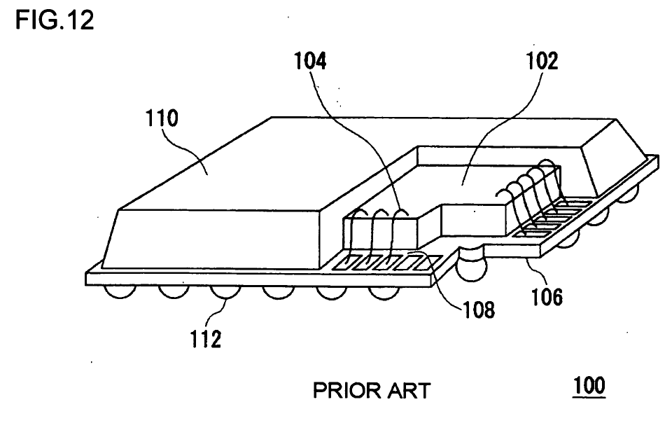

FIGS. 11A to 11D are sections illustrating a method of mounting semiconductor devices on the device mounting board 400 provided with the four-layer ISB structure according to a second embodiment of the present invention. The insulating resin film that contains glass fiber impregnated with epoxy resin according to this embodiment is the same as the insulating resin film 312 described in the first embodiment.

A variety of semiconductor apparatuses may be formed by mounting semiconductor devices on the device mounting board 400 described in the first embodiment. For example, devices may be mounted by flip chip bonding or wire bonding. Semiconductor devices may be mounted on the device mounting board 400 face up or face down. Semiconductor devices may be mounted on one side or both sides of the device mounting board 400. These forms of mounting may be combined in various ways.

More specifically, as illustrated in FIG. 11A, a semiconductor device 500 such as an LSI may be mounted on the top surface of the device mounting board 400 according to the first embodiment by flip chip bonding. In this process, electrode pads 402a and 402b on top of the device mounting board 400 are directly connected to electrode pads 502a and 502b of the semiconductor device 500, respectively. As illustrated in FIG. 11B, the semiconductor device 500 such as an LSI may be mounted on top of the device mounting board 400 in a face-up position. In this process, the electrodes 402a and 402b on top of the device mounting board 400 are wire bonded to the electrode pads 502a and 502b on top of the semiconductor device 500, respectively, by gold wires 504a and 504b, respectively.

As illustrated in FIG. 11C, the semiconductor device 500 such as an LSI may be mounted on top of the device mounting board 400 by flip-chip bonding, and a semiconductor device 600 such as an IC may be mounted on the bottom of the device mounting board 400 by flip chip bonding. In this process, the electrode pads 402a and 402b on top of the device mounting board 400 are directly connected to the electrode pads 502a and 502b of the semiconductor device 500, respectively. Also, electrode pads 404a and 404b on the bottom of the device mounting board 400 are directly connected to electrode pads 602a and 602b of the semiconductor device 600, respectively.

As illustrated in FIG. 11D, the semiconductor device 500 such as an LSI may be mounted on top of the device mounting board 400 in a face-up position, and the device mounting board 400 may be mounted on top of a printed circuit board 700. In this process, the electrode pads 402a and 402b on top of the device mounting board 400 are wire bonded to the electrode pads 502a and 502b on top of the semiconductor device 500, respectively, by gold wires 504a and 504b, respectively. The electrode pads 404a and 404b on the bottom of the device mounting board 400 are directly connected to electrode pads 702a and 702b on top of the printed circuit board 700, respectively.

In each of the described structures of the semiconductor apparatus is used the device mounting board 400, in which the insulating resin film 312 is implemented by an insulating resin film that contains glass fiber impregnated with epoxy resin, as described in the first embodiment. Therefore, the device mounting board 400 is excellent in properties such as heat resistance, rigidity, interlayer adhesion, parasitic capacitance. As such, the device mounting board 400 is a highly reliable and thin substrate. By mounting semiconductor devices on the device mounting board 400 in which the insulating resin film 312 is implemented by an insulating resin film that contains glass fiber impregnated with epoxy resin, a reliable and thin semiconductor apparatus is provided.

Semiconductor devices may be mounted on the device mounting board 400 in which the photo solder resist layer 328 is formed of a resin film including cardo type polymer. With this, the following effects are provided.

The photo solder resist layer 328 may be formed of, for example, a resin film including cardo type polymer. The photo solder resist layer 328 is excellent in properties such as heat resistance, rigidity, dielectric property and adhesion with devices. The photo solder resist layer 328 is also excellent in resolution. Therefore, by using a resin film including cardo type polymer to form the photo solder resist layer 328, the accuracy of dimension in mounting semiconductor devices on the device mounting board 400 is increased. Accordingly, by using a resin film including cardo type polymer to form the photo solder resist layer 328, the reliability of the device mounting board 400 is improved and the thickness thereof is reduced. Therefore, by mounting semiconductor devices on the device mounting board 400, in which a resin film including cardo type polymer is used to form the photo solder resist layer 328, a highly reliable and thin semiconductor apparatus is provided.

Given above is an explanation of the preferred embodiments of the invention. It is not intended that the present invention is limited to the described embodiments. Variations and modifications will be apparent to those skilled in the art, all of which fall within the scope of the present invention.

While the embodiments are described as using an insulating resin film that contains glass fiber impregnated with epoxy resin to form the insulating resin film 312 constituting the device mounting board 400, such an insulating resin film may be used to form the insulating resin film of a device mounting board other than the device mounting board 400, which is provided with the four-layer ISB structure.

While the embodiments are described as using the device mounting board 400 provided with the four-layer ISB structure comprising four wiring layers, a device mounting board with an ISB structure comprising more than four wiring layers may be used. For example, a substrate comprising six wiring layers may be used.

In the described embodiments, a resin film including cardo type polymer is used to form the photo solder resist layer 328 constituting the device mounting board 400. Alternatively, other materials may be used.

What is claimed is:

1. A device mounting board on which a device is mounted, the device mounting board comprising:
a substrate which includes a first insulating film;
a second insulating film which is provided on one surface of the substrate, wherein
the first insulating film and the second insulating film include glass fiber impregnated with epoxy resin, and the epoxy resin impregnation ratio of the second insulating film is higher than that of the first insulating film.

2. The device mounting board according to claim 1, wherein the film thickness of the second insulating film is smaller than that of the first insulating film.

3. The device mounting board according to claim 1, wherein wiring is provided between the substrate and the second insulating film.

4. The device mounting board according to claim 1, wherein the epoxy resin impregnation ratio of the second insulating film ranges from 71 Vol % to 75 Vol %.

5. The device mounting board according to claim 2, wherein the epoxy resin impregnation ratio of the second insulating film ranges from 71 Vol % to 75 Vol %.

6. The device mounting board according to claim 3, wherein the epoxy resin impregnation ratio of the second insulating film ranges from 71 Vol % to 75 Vol %.

7. The device mounting board according to claim 1, wherein the glass-transition temperature of the second insulating film ranges from 160° C. to 170° C., and the bending modulus of elasticity of the second insulating film ranges from 27 GPa to 30 GPa.

8. The device mounting board according to claim 2, wherein the glass-transition temperature of the second insulating film ranges from 160° C. to 170° C., and the bending modulus of elasticity of the second insulating film ranges from 27 GPa to 30 GPa.

9. The device mounting board according to claim 3, wherein the glass-transition temperature of the second insulating film ranges from 160° C. to 170° C., and the bending modulus of elasticity of the second insulating film ranges from 27 GPa to 30 GPa.

10. The device mounting board according to claim 4, wherein the glass-transition temperature of the second insulating film ranges from 160° C. to 170° C., and the bending modulus of elasticity of the second insulating film ranges from 27 GPa to 30 GPa.

11. The device mounting board according to claim 1, further comprising a third insulating film provided on the other surface of the substrate, wherein
the third insulating film includes glass fiber impregnated with epoxy resin, and the epoxy resin impregnation ratio of the third insulating film is higher than that of the first insulating film.

12. The device mounting board according to claim 2, further comprising a third insulating film provided on the other surface of the substrate, wherein
the third insulating film includes glass fiber impregnated with epoxy resin, and the epoxy resin impregnation ratio of the third insulating film is higher than that of the first insulating film.

13. The device mounting board according to claim 3, further comprising a third insulating film provided on the other surface of the substrate, wherein
the third insulating film includes glass fiber impregnated with epoxy resin, and the epoxy resin impregnation ratio of the third insulating film is higher than that of the first insulating film.

14. The device mounting board according to claim 4, further comprising a third insulating film provided on the other surface of the substrate, wherein
the third insulating film includes glass fiber impregnated with epoxy resin, and the epoxy resin impregnation ratio of the third insulating film is higher than that of the first insulating film.

15. The device mounting board according to claim 7, further comprising a third insulating film provided on the other surface of the substrate, wherein
the third insulating film includes glass fiber impregnated with epoxy resin, and the epoxy resin impregnation ratio of the third insulating film is higher than that of the first insulating film.

16. The device mounting board according to claim 11, wherein the epoxy resin impregnation ratio of the third insulating film ranges from 71 Vol % to 75 Vol %.

17. The device mounting board according to claim 1, wherein wiring for connecting the devices are provided on the second insulating film, and a fourth insulating film is provided on the wiring so that the devices and the wiring are covered by the fourth insulating film.

18. The device mounting board according to claim 4, wherein wiring for connecting the devices are provided on the second insulating film, and a fourth insulating film is provided on the wiring so that the devices and the wiring are covered by the fourth insulating film.

19. The device mounting board according to claim 7, wherein wiring for connecting the devices are provided on the second insulating film, and a fourth insulating film is provided on the wiring so that the devices and the wiring are covered by the fourth insulating film.

20. The device mounting board according to claim 17, wherein the fourth insulating film is a photo solder resist layer including cardo type polymer.
